(19) United States
(12) Patent Application Publication
(10) Pub. No.: US 2022/0108949 A1
(43) Pub. Date: Apr. 7, 2022

(54) SEMICONDUCTOR PACKAGES INCLUDING A U-SHAPED RAIL

(71) Applicant: Infineon Technologies AG, Neubiberg (DE)

(72) Inventors: Lee Shuang WANG, Melaka (MY); Thai Kee GAN, Melaka (MY); Teck Sim LEE, Melaka (MY)

(73) Assignee: Infineon Technologies AG, Neubiberg (DE)

(21) Appl. No.: 17/064,954

(22) Filed: Oct. 7, 2020

(51) Int. Cl. H01L 23/528; H01L 23/31; H01L 43/04; G01R 33/09; G01R 33/07

(52) U.S. Cl. CPC H01L 23/5283; H01L 23/3157; G01R 33/07; G01R 33/09; H01L 43/04

(57) ABSTRACT

One example of a semiconductor package includes a first die pad, a first die, a second die pad, and a second die. The first die pad includes a main portion and a U-shaped rail portion extending from the main portion. The first die is electrically coupled to the first die pad. The second die pad is proximate the U-shaped rail portion of the first die pad. The second die is electrically coupled to the second die pad. The second die includes a magnetic field sensor.

### BACKGROUND

An electronic device may include a sensor integrated in a high voltage package, such as a high voltage half bridge package. It is desirable to improve the sensing capability within the high voltage package.

For these and other reasons, a need exists for the present disclosure.

### SUMMARY

One example of a semiconductor package includes a first die pad, a first die, a second die pad, and a second die. The first die pad includes a main portion and a U-shaped rail portion extending from the main portion. The first die is electrically coupled to the first die pad. The second die pad is proximate the U-shaped rail portion of the first die pad. The second die is electrically coupled to the second die pad. The second die includes a magnetic field sensor.

Another example of a semiconductor package includes a first die pad, a first die, a second die pad, a second die, a third die pad, and a third die. The first die pad includes a main portion and a U-shaped rail portion extending from the main portion. The U-shaped rail portion includes a first portion extending from the main portion, a second portion extending from the first portion, and a third portion extending from the second portion. The second portion is perpendicular to the first portion and the third portion. The first die is electrically coupled to the first die pad. The second die is electrically coupled to the second die pad and aligned with the U-shaped rail portion of the first die pad. The second die includes a magnetic field sensor. The third die is electrically coupled to the third die pad and the first die pad.

One example of a method for sensing a current includes enabling a high voltage half bridge circuit including a high side transistor and a low side transistor to output a current. The method further includes directing the current through a U-shaped rail of a die pad coupled to the low side transistor. The method further includes sensing a magnetic field generated by the current through the U-shaped rail via a magnetic field sensor spaced apart and aligned with the U-shaped rail to determine a magnitude of the current through the U-shaped rail.

### BRIEF DESCRIPTION OF THE DRAWINGS

FIG. 1 illustrates a bottom view of one example of a semiconductor package without mold material.

FIG. 2 illustrates a bottom view of another example of a semiconductor package without mold material.

FIG. 3 is a schematic diagram illustrating one example of a high voltage half bridge circuit including a sensor.

FIG. 4 illustrates a bottom view of the semiconductor package of FIG. 2 including additional details.

FIGS. 5A and 5B illustrate a top view and a bottom view, respectively, of the semiconductor package of FIG. 2 with mold material.

FIG. 6 illustrates a top perspective view of one example of a semiconductor package including a groove within the mold material.

FIGS. 7A and 7B illustrate a bottom perspective view without mold material and a top view with mold material, respectively, of another example of a semiconductor package.

FIGS. 8A and 8B illustrate a bottom perspective view without mold material and a top view with mold material, respectively, of another example of a semiconductor package.

FIGS. 9A and 9B illustrate a bottom perspective view without mold material and a top view with mold material, respectively, of another example of a semiconductor package.

FIGS. 10A and 10B are flow diagrams illustrating one example of a method for sensing a current.

### DETAILED DESCRIPTION

In the following detailed description, reference is made to the accompanying drawings which form a part hereof, and in which is shown by way of illustration specific examples in which the disclosure may be practiced. It is to be understood that other examples may be utilized and structural or logical changes may be made without departing from the scope of the present disclosure. The following detailed description, therefore, is not to be taken in a limiting sense, and the scope of the present disclosure is defined by the appended claims. It is to be understood that features of the various examples described herein may be combined, in part or whole, with each other, unless specifically noted otherwise.

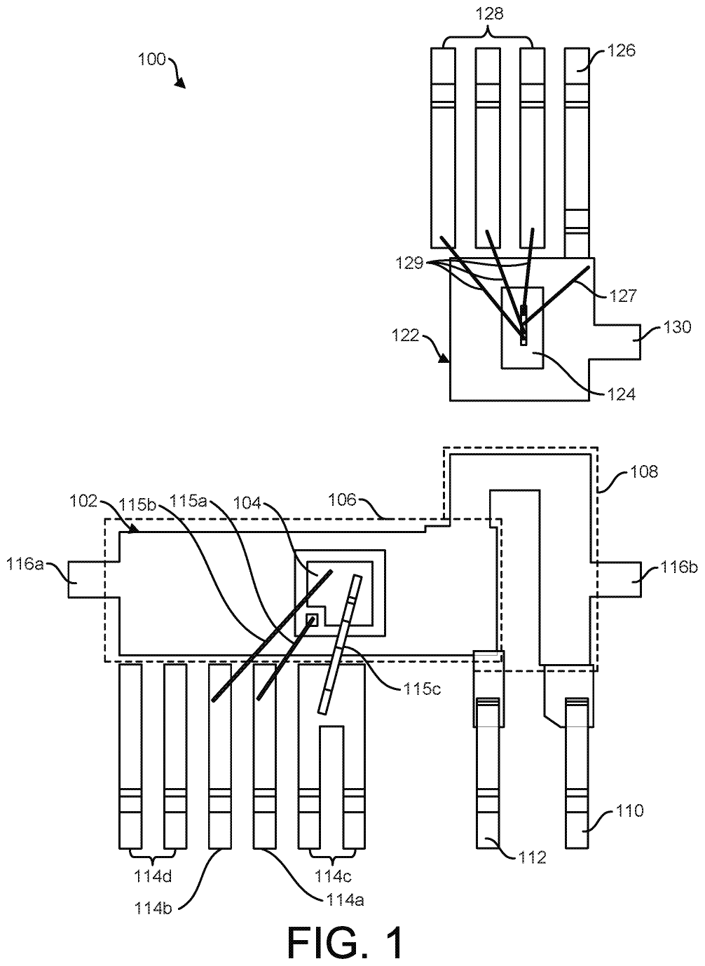

FIG. 1 illustrates a bottom view of one example of a semiconductor package 100 without mold material. Semiconductor package 100 includes a first die pad 102, a first die 104, a second die pad 122, and a second die 124. The first die pad 102 includes a main portion (as indicated within dashed lines 106) and a U-shaped rail portion extending from the main portion (as indicated within dashed lines 108). The first die 104 is electrically coupled to the first die pad 102 (e.g., via a contact pad on a surface of the first die 104 facing the first die pad 102). The second die pad 122 is proximate the U-shaped rail portion 108 of the first die pad 102. In one example, the second die pad 122 is aligned with the U-shaped rail portion 108. The second die 124 is electrically coupled to the second die pad 122 (e.g., via a bond wire 127). The second die 124 includes a magnetic field sensor.

In one example, the magnetic field sensor includes a tunnel-magnetoresistance (TMR) sensor. In other examples, the magnetic field sensor includes a Hall effect sensor, an anisotropic magnetoresistance (AMR) sensor, a giant magnetoresistance (GMR) sensor, or another suitable sensor. The magnetic field sensor is configured to sense a magnetic field generated by a current passing through the U-shaped rail portion 108 of the first die pad 102.

Semiconductor package 100 further includes a first lead 110 coupled (e.g., directly coupled) to a first side of the U-shaped rail portion 108 of the first die pad 102 and a second lead 112 coupled (e.g., directly coupled) to the main portion 106 of the first die pad 106 and parallel to and directly adjacent to the first lead 110. In one example, the U-shaped rail portion 108 of the first die pad 102 and the first lead 110 are configured to conduct a current and the second lead 112 is a dummy lead (e.g., does not conduct a current) such that 100 percent of a total current to be output by semiconductor package 100 passes through the U-shaped rail portion 108 to a device external to semiconductor package 100. In other examples, the second lead 112 is not a dummy lead and the first lead 110 may conduct about 50 percent of the total current and the second lead 112 may conduct about 50 percent of the total current to a device external to semiconductor package 100. Accordingly, in this example, about 50 percent of the total current will pass through the U-shaped rail portion 108.

Semiconductor package 100 may further include leads 114a-114d proximate first die pad 102, lead 126 electrically coupled (e.g., directly coupled) to second die pad 122, leads 128 proximate second die pad 122, tie bars 116a and 116b coupled (e.g., directly coupled) to first die pad 102, and tie bar 130 coupled (e.g., directly coupled) to second die pad 122. Leads 114a-114d may be arranged on the same side of first die pad 102 as first lead 110 and second lead 112. Leads 114a, 114b, and 114c may be spaced apart from lead 112 and electrically coupled to first die 104 through bond wires 115a, 115b, and 115c, respectively. In other examples, leads 114a-114c may be electrically coupled to first die 104 through clips or other suitable conductors. Leads 114d may be dummy leads and electrically isolated. Leads 128 may be arranged on the same side of second die pad 122 as lead 126. Leads 128 may be electrically coupled to second die 124 through bond wires 129. In other examples, leads 128 may be electrically coupled to second die 124 through clips or other suitable conductors.

Tie bar 116a and 116b may be on opposite sides of the first die pad 102 such that tie bar 116a is attached to the main portion 106 of the first die pad 102 and second tie bar 116b is attached to the U-shaped rail portion 108 of the first die pad 102. Tie bar 130 is attached to second die pad 122 and may be arranged on the same side of semiconductor package 100 as tie bar 116b. The die pads 102 and 122 and the leads 110, 112, 114a-114d, 126, and 128 of semiconductor package 100 may be made of a metal or have a metal surface, such as Ag, Cu, Ni/Pd/Au, NiNiP, or Ni/Pd/AuAg.

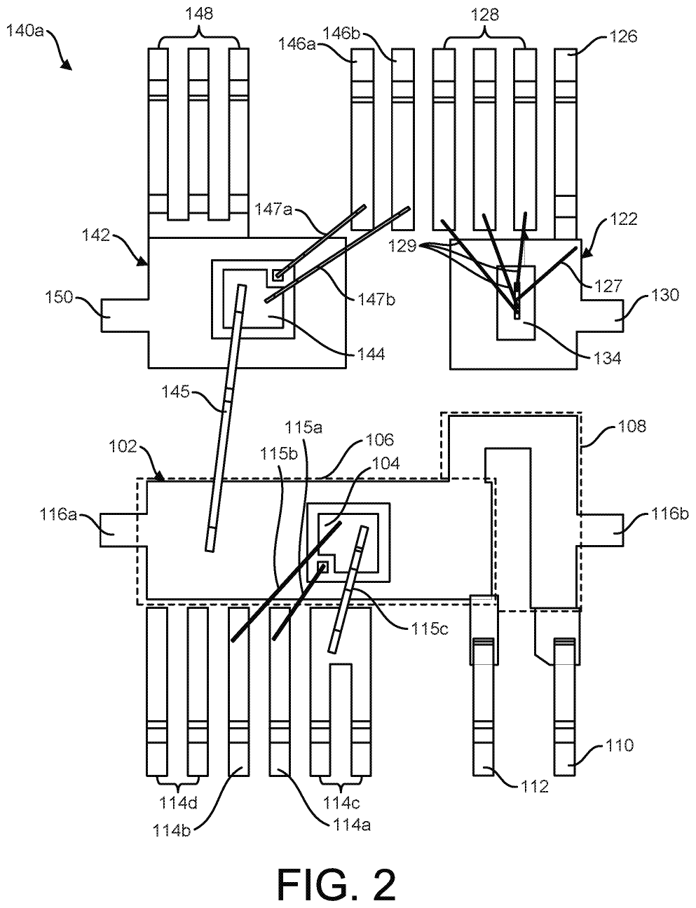

FIG. 2 illustrates a bottom view of another example of a semiconductor package 140a without mold material. Semiconductor package 140a is similar to semiconductor package 100 previously described and illustrated with reference to FIG. 1, except that semiconductor package 140a also includes a third die pad 142 and a third die 144. Third die 144 may be electrically coupled to the third die pad 142 (e.g., via a contact pad on a surface of the third die 144 facing the third die pad 142) and the first die pad 102 (e.g., via a bond wire 145, clip, or other suitable conductor). Semiconductor package 140a further includes leads 146a and 146b, leads 148, and tie bar 150. Leads 146a and 146b may be spaced apart from leads 148 and proximate to leads 128. Leads 146a and 146b may be electrically coupled to third die 144 through bond wires 147a and 147b, respectively. In other examples, leads 146a and 146b may be electrically coupled to third die 144 through clips or other suitable conductors. Leads 148 are electrically coupled (e.g., directly coupled) to third die pad 142. Tie bar 150 may be opposite to tie bar 130 and on the same side of semiconductor package 140a as tie bar 116a.

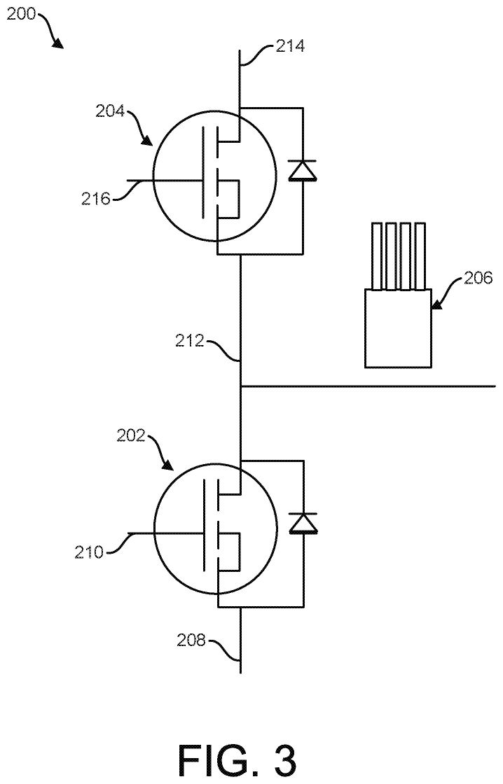

In one example, the first die 104 includes a first power transistor, the second die 124 includes a magnetic field sensor, and the third die 144 includes a second power transistor. In this example, lead 114a may be a gate lead, lead 114b be a sense lead, and leads 114c may be source leads for the first power transistor of first die 104. Lead 146a may be a gate lead, lead 146b may be a sense lead, and leads 148 may be drain leads for the second power transistor of third die 144. The first power transistor and the second power transistor may be configured in a high voltage half bridge circuit with a magnetic field sensor as further described and illustrated below with reference to the following FIG. 3.

FIG. 3 is a schematic diagram illustrating one example of a high voltage half bridge circuit 200 including a sensor 206. The high voltage half bridge circuit 200 includes a first power transistor 202 and a second power transistor 204. The drain of the first power transistor 202 is electrically coupled to the source of the second power transistor 204 through a signal path 212. The source of the first power transistor 202 is electrically coupled to a signal path 208, and the gate of the first power transistor 202 is electrically coupled to a signal path 210. The drain of the second power transistor 204 is electrically coupled to a signal path 214, and the gate of the second power transistor 204 is electrically coupled to a signal path 216. The sensor 206 is proximate the signal path 212 to sense a magnetic field generated by a current passing through the signal path 212.

In one example, first power transistor 202 is provided by first die 104, second power transistor 204 is provided by third die 144, and sensor 206 is provided by second die 124 as previously described and illustrated with reference to FIG. 2. In one example, signal path 212 may include first die pad 102 and bond wire 145, where the portion of signal path 212 proximate sensor 206 is provided by the U-shaped rail portion 108 of first die pad 102. Signal path 208 may be provided by leads 114c and bond wire 115c, signal path 210 may be provided by lead 114a and bond wire 115a, signal path 214 may be provided by third die pad 142 and leads 148, and signal path 216 may be provided by lead 146a and bond wire 147a.

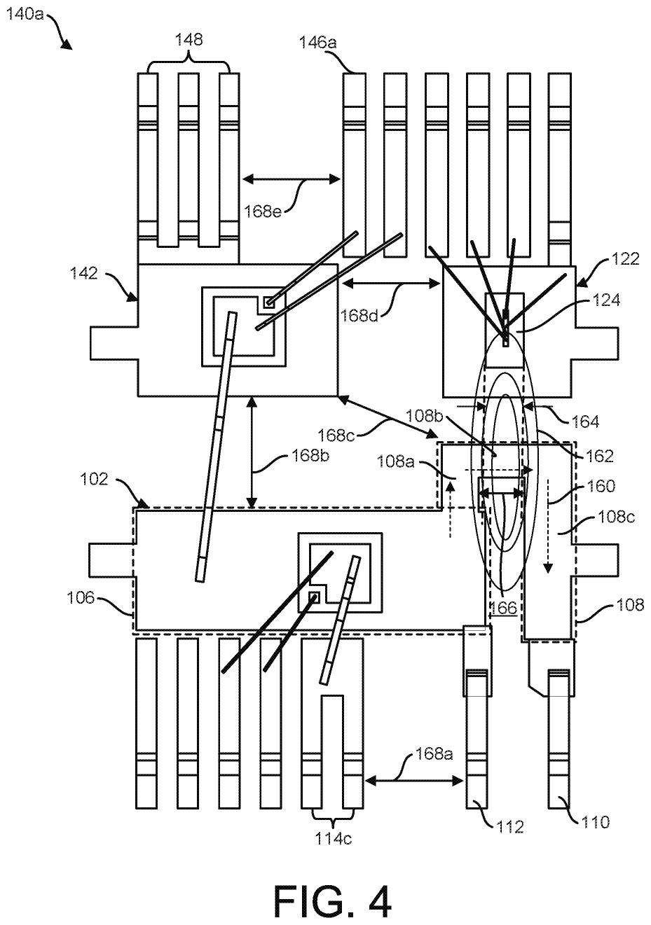

FIG. 4 illustrates a bottom view of the semiconductor package 140a of FIG. 2 including additional details. When a current passes through the U-shaped rail portion 108 as indicated at 160, a magnetic field is generated as indicated at 162. While the current 160 is indicated as passing from the main portion 106 of the first die pad 102 through the U-shaped rail portion 108 and toward the first lead 110, in other examples, the current may be passed from the first lead 110 through the U-shaped rail portion 108 toward the main portion 106 of the first die pad 102. The magnetic field 162 may be sensed by the magnetic field sensor of the second die 124. Based on the sensed magnetic field, the magnitude and direction of the current through the U-shaped rail portion 108 may be determined. Based on the determined magnitude and direction of the current through the U-shaped rail portion 108, the operation of semiconductor package 140a may be monitored and/or controlled.

In further detail, the U-shaped rail portion 108 includes a first portion 108a extending from the main portion 106 of the second die pad 102, a second portion 108b extending from the first portion 108a, and a third portion 108c extending from the second portion. The second portion 108b is perpendicular to the first portion 108a and the third portion 108c. The first portion 108a is shorter than the third portion 108c. A gap between the first portion 108a and the third portion 108c has a width 166 in a direction parallel to the second portion 108b. The second die 124 has a width indicated at 164 in a direction parallel to the second portion 108b. The width 166 of the gap within the U-shaped rail portion 108 of the first die pad 102 may be greater than the width 164 of the second die 124. In addition, the second die 124 may be aligned (e.g., center aligned) with the U-shaped rail portion 108. The magnetic field sensor of the second die 124 may be perpendicular to the U-shaped rail portion 108 and centered with the U-shaped rail portion 108 for optimum sensing of the magnetic field 162 generated by a current 160 passing through the U-shaped rail portion 108.

The second lead 112 may be spaced apart from the leads 114c by a distance indicated at 168a in a direction perpendicular to the adjacent sides of leads 112 and 114c. The main portion 106 of the first die pad 102 may be spaced apart from the third die pad 142 by a distance indicated at 168b in a direction perpendicular to the adjacent sides of the first die pad 102 and the second die pad 142. The U-shaped rail portion 108 of the first die pad 102 may be spaced apart from the third die pad 142 by a distance indicated at 168c between the corner of third die pad 142 closest to the U-shaped rail portion 108 and the corner of U-shaped rail portion 108 closest to third die pad 142. The second die pad 122 may be spaced apart from the third die pad 142 by a distance indicated at 168d in a direction perpendicular to the adjacent sides of the second die pad 122 and the third die pad 142. The lead 146a may be spaced apart from the leads 148 by a distance indicated at 168e in a direction perpendicular to the adjacent sides of leads 146a and 148. Each distance 168a-168e may be selected to provide sufficient creepage distances for high voltage performance. The configuration of the U-shaped rail portion 108 enables the second portion 108b to be closer to the second die pad 122 while maintaining sufficient creepage distances between the first die pad 102 and the third die pad 142 (e.g., as indicated by distances 168b and 168c).

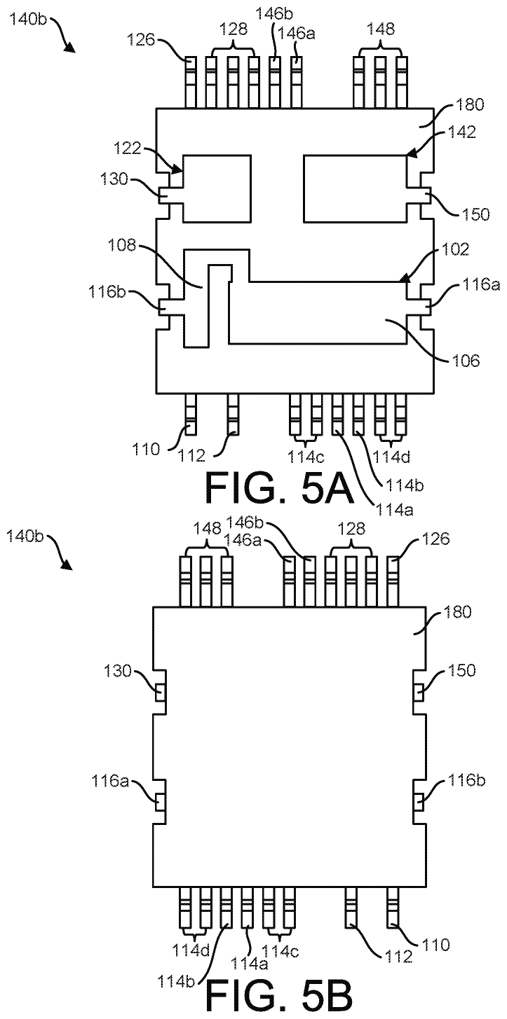

FIGS. 5A and 5B illustrate a top view and a bottom view, respectively, of a semiconductor package 140b. Semiconductor package 140b is similar to semiconductor package 140a previously described and illustrated with reference to FIG. 2, except that semiconductor package 140b includes mold material 180. The mold material 180 encapsulates at least a portion of the first die pad 102, the second die pad 122, and the third die pad 142. In this example, the first die pad 102 including the main portion 106 and the U-shaped rail portion 108, the second die pad 122, and the third die pad 142 are exposed on the top side of the semiconductor package 140b as shown in FIG. 5A. The mold material 180 fully encapsulates the first die 104, the second die 124, the third die 144, and the bond wires 115a-115c, 127, 129, 145, 147a, and 147b. The mold material 180 also encapsulates at least a portion of each lead 110, 112, 114a-114d, 126, 128, 146a, 146b, and 148 and a portion of each tie bar 116a, 116b, 130, and 150. The mold material 180 may include an epoxy or another suitable dielectric material.

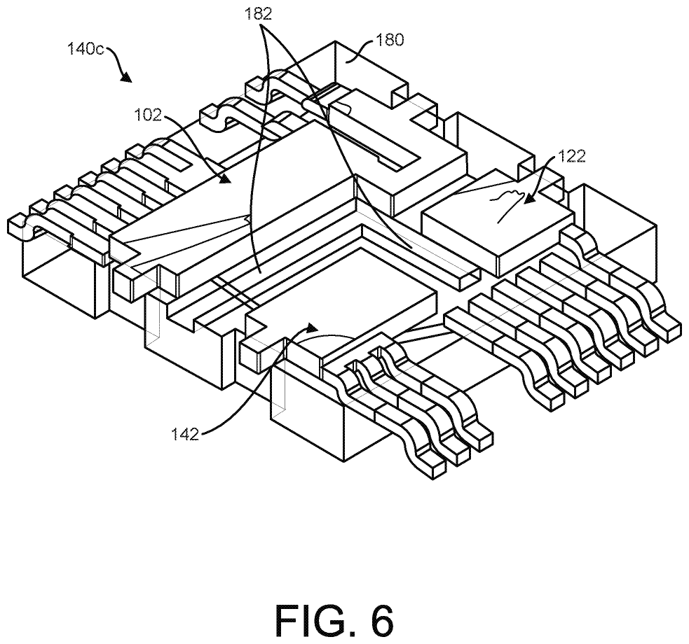

FIG. 6 illustrates a top perspective view of one example of a semiconductor package 140c. Semiconductor package 140c is similar to semiconductor package 140a previously described and illustrated with reference to FIG. 2, except that semiconductor package 140c includes a groove 182 within a mold material 180. The groove 182 within the mold material 180 extends between the first die pad 102 and the third die pad 142 and between the second die pad 122 and the third die pad 142. The groove 182 increases the creepage distance between the first die pad 102 and the third die pad 142 and between the second die pad 122 and the third die pad 142. By increasing the creepage distance, the groove 182 may increase the high voltage capability of the semiconductor package 140c.

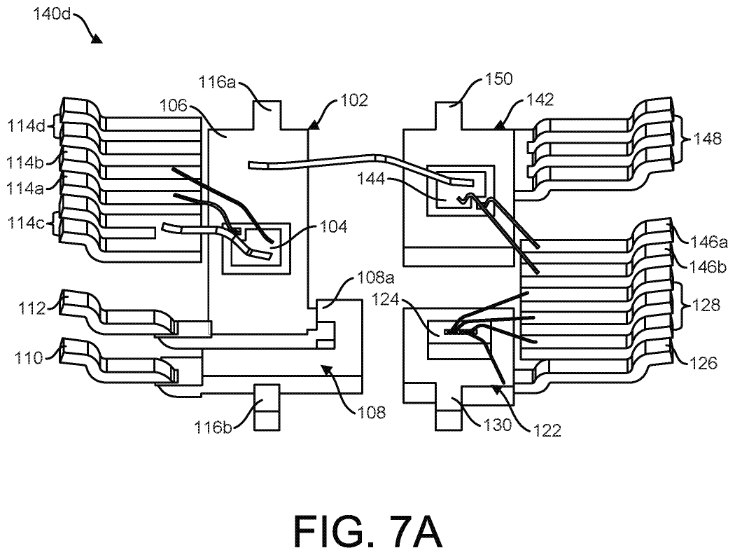

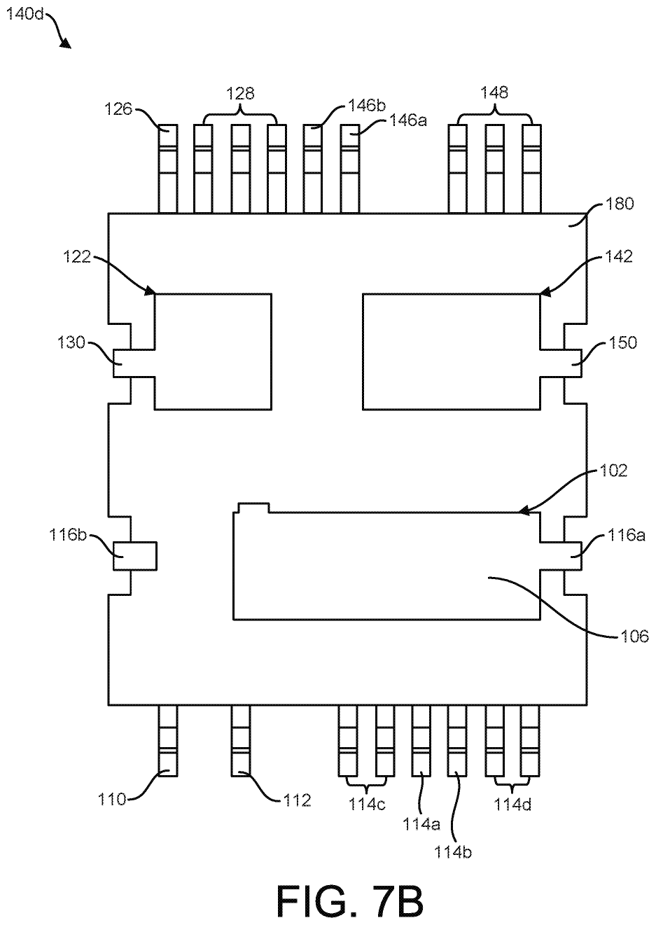

FIGS. 7A and 7B illustrate a bottom perspective view without mold material 180 and a top view with mold material 180, respectively, of another example of a semiconductor package 140d. Semiconductor package 140d is similar to semiconductor package 140b previously described and illustrated with reference to FIGS. 5A and 5B, except that in semiconductor package 140d, the U-shaped rail portion 108 is vertically offset with respect to the main portion 106 of the first die pad 102. As shown in FIG. 7A, a section of the first portion 108a of the U-shaped rail portion 108 is bent (e.g., via stamping) to vertically offset the remaining portions of the U-shaped rail portion 108 with respect to the main portion 106 of the first die pad 102. As a result, the U-shaped rail portion 108 is fully encapsulated by the mold material 180 as shown in FIG. 7B while the main portion 106 of the first die pad 102, the second die pad 122, and the third die pad 142 remain exposed. In this example, compared to semiconductor package 140b of Figures SA and 5B, the U-shaped rail portion 108 of semiconductor package 140d may be closer to the magnetic field sensor of the second die 124.

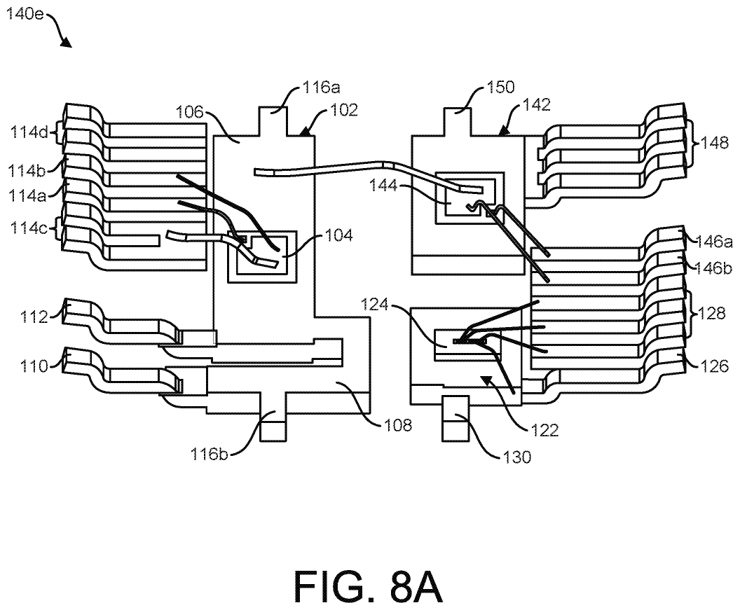

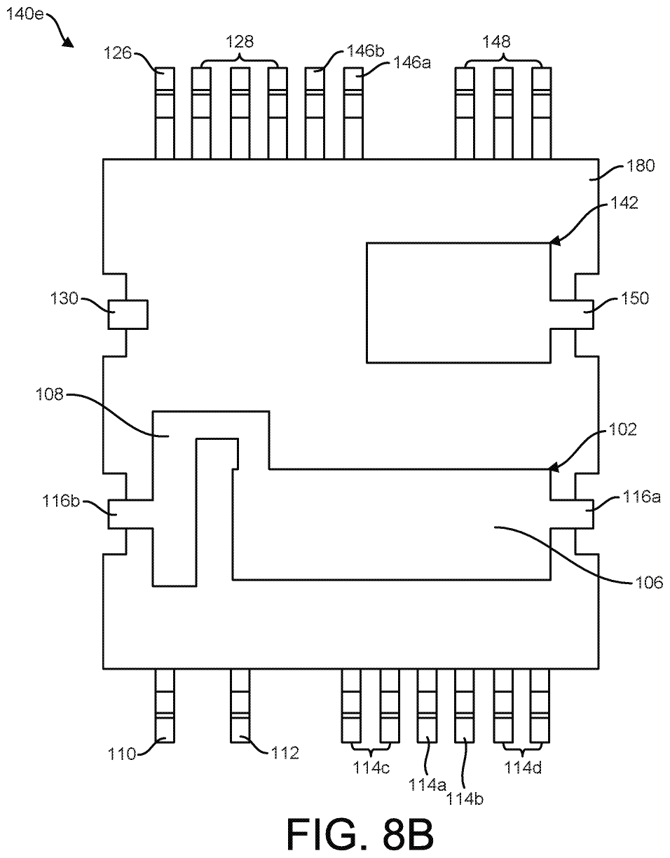

FIGS. 8A and 8B illustrate a bottom perspective view without mold material 180 and a top view with mold material 180, respectively, of another example of a semiconductor package 140e. Semiconductor package 140e is similar to semiconductor package 140b previously described and illustrated with reference to FIGS. 5A and 5B, except that in semiconductor package 140e, the second die pad 122 is vertically offset with respect to the first die pad 102 and the third die pad 142. As shown in FIG. 8A, a section of the tie bar 130 and a section of the lead 126 are bent (e.g., via stamping) to vertically offset the second die pad 122 with respect to the tie bar 130 and the lead 126. As a result, the second die pad 122 is fully encapsulated by the mold material 180 as shown in FIG. 8B while the third die pad 142 and the first die pad 102 including the main portion 106 and the U-shaped rail portion 108 remain exposed.

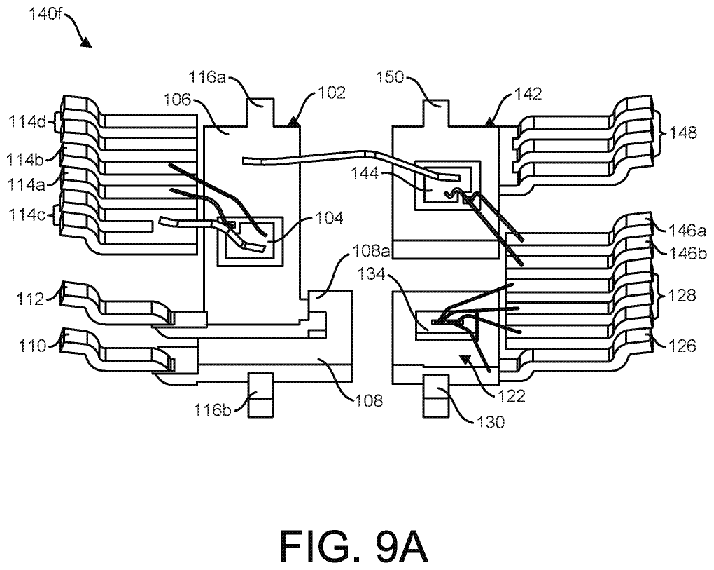

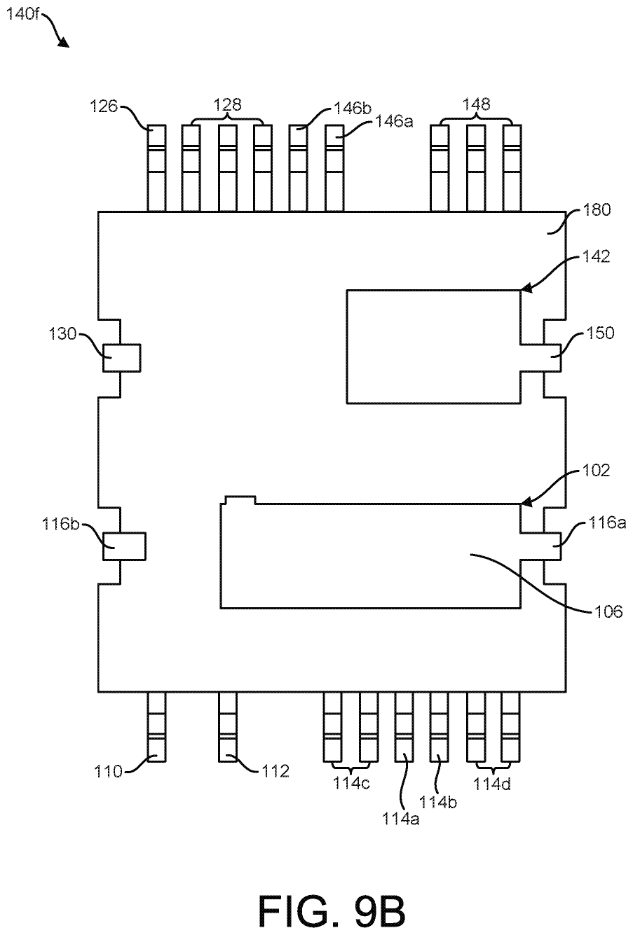

FIGS. 9A and 9B illustrate a bottom perspective view without mold material 180 and a top view with mold material 180, respectively, of another example of a semiconductor package 140f. Semiconductor package 140f is similar to semiconductor package 140b previously described and illustrated with reference to FIGS. 5A and 5B, except that in semiconductor package 140f, the U-shaped rail portion 108 is vertically offset with respect to the main portion 106 of the first die pad 102 and the second die pad 122 is vertically offset with respect to the main portion 106 of the first die pad 102 and the third die pad 142. In one example, the second die pad 122 and the U-shaped rail portion 108 may be vertically offset by the same distance. In other examples, the second die pad 122 and the U-shaped rail portion 108 may be vertically offset by different distances. As shown in FIG. 9A, a section of the first portion 108a of the U-shaped rail portion 108 is bent (e.g., via stamping) to vertically offset the remaining portions of the U-shaped rail portion 108 with respect to the main portion 106 of the first die pad 102. In addition, a section of the tie bar 130 and a section of the lead 126 are bent (e.g., via stamping) to vertically offset the second die pad 122 with respect to the tie bar 130 and the lead 126. As a result, the U-shaped rail portion 108 and the second die pad 122 are fully encapsulated by the mold material 180 as shown in FIG. 9B while the main portion 106 of the first die pad 102 and the third die pad 142 remain exposed.

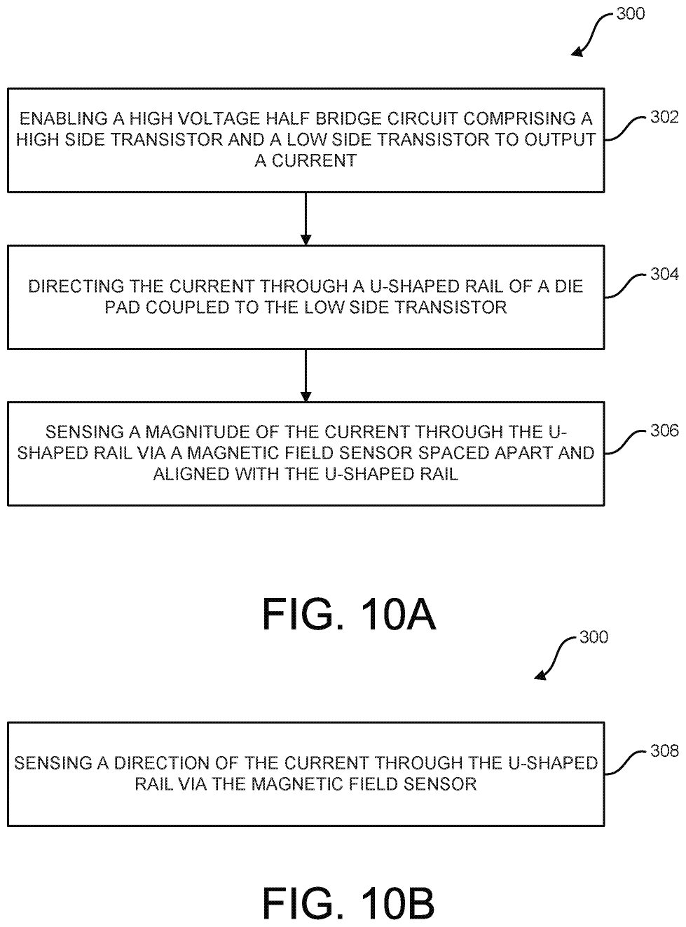

FIGS. 10A and 10B are flow diagrams illustrating one example of a method 300 for sensing a current. In one example, semiconductor package 100 or 140a-140f previously described and illustrated with reference to FIGS. 1, 2, and 4-9B may be used to implement method 300. As illustrated in FIG. 10A at 302, method 300 includes enabling a high voltage half bridge circuit comprising a high side transistor (e.g., third die 144 or transistor 204) and a low side transistor (e.g., first die 104 or transistor 210) to output a current (e.g., to first die pad 102 or signal path 212). At 304, method 300 includes directing the current through a U-shaped rail of a die pad (e.g., U-shaped rail 108 of first die pad 102) coupled to the low side transistor. At 306, method 300 includes sensing a magnetic field generated by the current through the U-shaped rail via a magnetic field sensor (e.g., second die 124 or sensor 206) spaced apart and aligned with the U-shaped rail to determine a magnitude of the current through the U-shaped rail. As illustrated in FIG. 10B at 308, method 300 may further include sensing the magnetic field generated by the current through the U-shaped rail via the magnetic field sensor to determine a direction of the current through the U-shaped rail.

Although specific examples have been illustrated and described herein, a variety of alternate and/or equivalent implementations may be substituted for the specific examples shown and described without departing from the scope of the present disclosure. This application is intended to cover any adaptations or variations of the specific examples discussed herein. Therefore, it is intended that this disclosure be limited only by the claims and the equivalents thereof.

1. A semiconductor package comprising:
a first die pad comprising a main portion and a U-shaped rail portion extending from the main portion;
a first die electrically coupled to the first die pad;
a second die pad proximate the U-shaped rail portion of the first die pad; and
a second die electrically coupled to the second die pad, the second die comprising a magnetic field sensor.

2. The semiconductor package of claim 1, wherein the magnetic field sensor comprises a tunnel-magnetoresistance (TMR) sensor.

3. The semiconductor package of claim 1, wherein the magnetic field sensor comprises a Hall effect sensor, an anisotropic magnetoresistance (AMR) sensor, or a giant magnetoresistance (GMR) sensor.

4. The semiconductor package of claim 1, wherein the magnetic field sensor is to sense a magnetic field generated by a current through the U-shaped rail portion of the first die pad.

5. The semiconductor package of claim 1, wherein a width of a gap within the U-shaped rail portion of the first die pad is greater than a width of the second die.

6. The semiconductor package of claim 1, further comprising:
a first lead coupled to a first side of the U-shaped rail portion of the first die pad; and
a second lead coupled to the main portion of the first die pad and parallel to and directly adjacent to the first lead.

7. The semiconductor package of claim 6, wherein the U-shaped rail portion of the first die pad and the first lead are to conduct a current and the second lead is a dummy lead.

8. The semiconductor package of claim 1, further comprising:
a third die pad; and
a third die electrically coupled to the third die pad and the first die pad.

9. The semiconductor package of claim 8, further comprising:
a mold material encapsulating at least a portion of the first die pad, the first die, the second die pad, the second die, the third die pad, and the third die.

10. The semiconductor package of claim 9, further comprising:
a groove within the mold material extending between the first die pad and the third die pad and between the second die pad and the third die pad.

11. The semiconductor package of claim 9, wherein the second die pad is closer to the U-shaped rail portion of the first die pad than to the main portion of the first die pad and the third die pad.

12. The semiconductor package of claim 9, wherein the first die pad and the third die pad are exposed on a top side of the semiconductor package.

13. The semiconductor package of claim 12, wherein the second die pad is exposed on the top side of the semiconductor package.

14. The semiconductor package of claim 12, wherein the U-shaped rail portion is exposed on the top side of the semiconductor package.

15. The semiconductor package of claim 12, wherein the U-shaped rail portion is fully encapsulated by the mold material.

16. A semiconductor package comprising:
a first die pad comprising a main portion and a U-shaped rail portion extending from the main portion, the U-shaped rail portion comprising a first portion extending from the main portion, a second portion extending from the first portion, and a third portion extending from the second portion, the second portion perpendicular to the first portion and the third portion;
a first die electrically coupled to the first die pad;
a second die pad;
a second die electrically coupled to the second die pad and aligned with the U-shaped rail portion of the first die pad, the second die comprising a magnetic field sensor;
a third die pad; and
a third die electrically coupled to the third die pad and the first die pad.

17. The semiconductor package of claim 16, wherein the first die comprises a first power transistor and the third die comprises a second power transistor, a drain of the first power transistor electrically coupled to a source of the second power transistor.

18. The semiconductor package of claim 16, further comprising:
a mold material encapsulating at least a portion of the first die pad, the first die, the second die pad, the second die, the third die pad, and the third die such that the first die pad, the second die pad, and the third die pad are exposed on a top side of the semiconductor package.

19. A method for sensing a current, the method comprising:
enabling a high voltage half bridge circuit comprising a high side transistor and a low side transistor to output a current;
directing the current through a U-shaped rail of a die pad coupled to the low side transistor; and
sensing a magnetic field generated by the current through the U-shaped rail via a magnetic field sensor spaced apart and aligned with the U-shaped rail to determine a magnitude of the current through the U-shaped rail.

20. The method of claim 19, further comprising:
sensing the magnetic field generated by the current through the U-shaped rail via the magnetic field sensor to determine a direction of the current through the U-shaped rail.
